(19) United States
(12) Patent Application Publication
(10) Pub. No.: US 2025/0015062 A1
(43) Pub. Date: Jan. 9, 2025

(54) SEMICONDUCTOR PACKAGE

(71) Applicant: SAMSUNG ELECTRONICS CO., LTD., Suwon-si (KR)

(72) Inventor: Junghoon KANG, Suwon-si (KR)

(73) Assignee: SAMSUNG ELECTRONICS CO., LTD., Suwon-si (KR)

(21) Appl. No.: 18/421,723

(22) Filed: Jan. 24, 2024

(30) Foreign Application Priority Data
Jul. 6, 2023 (KR) 10-2023-0087786

(51) Int. Cl. H01L 25/10; H01L 23/00; H01L 23/15; H01L 23/31; H01L 23/48; H01L 23/498; H01L 23/538; H01L 25/065

(52) U.S. Cl. CPC H01L 25/105; H01L 23/15; H01L 23/3121; H01L 23/3135; H01L 23/481; H01L 23/49822; H01L 23/49894; H01L 23/5383; H01L 24/08; H01L 24/16; H01L 24/48; H01L 25/0655; H01L 2224/08235; H01L 2224/16227; H01L 2224/48227; H01L 2225/1023; H01L 2225/1041; H01L 2225/1058; H01L 2924/3511

(57) ABSTRACT

A semiconductor package includes: a first redistribution substrate; a module structure on the first redistribution substrate; a first molding layer on the first redistribution substrate and surrounding the module structure; and a vertical connection structure on a side of the module structure, the vertical connection structure vertically extending and connected to the first redistribution substrate, wherein the module structure includes: an interposer substrate including a glass substrate, and a first semiconductor chip mounted on the interposer substrate; and a second semiconductor chip mounted on the interposer substrate.

### CROSS-REFERENCE TO RELATED APPLICATION

This application is based on and claims priority under 35 U.S.C § 119 to Korean Patent Application No. 10-2023-0087786, filed on Jul. 6, 2023, in the Korean Intellectual Property Office, the disclosure of which is incorporated by reference herein in its entirety.

### BACKGROUND

The disclosure relates to a semiconductor package and a method of fabricating the same, and more particularly, to a semiconductor package including a connection substrate and a method of fabricating the same.

A semiconductor package is provided to implement an integrated circuit chip suitable for use in electronic products. With the recent development of the electronic industry, semiconductor packages are variously developed to achieve goals such as compact size, small weight, and low manufacturing cost. A size of semiconductor chip becomes smaller with high integration of the semiconductor chip. However, it is difficult to adhere, handle, and test solder balls due to small sizes of the semiconductor chip. Additionally, it occurs problems of acquiring diversified mount boards in accordance with the small sizes of the semiconductor chip. A fan-out panel level package (FO-PLP) is proposed to solve the above-described problems. In fan-out panel semiconductor packages, the area of redistribution lines is inevitably greater than that of the semiconductor chip. Accordingly, there is a problem in that an excessively large area is allocated to the semiconductor chip compared to the utilization of the semiconductor chip.

### SUMMARY

Provided are a semiconductor package in which electrical properties are improved and a method of fabricating the same.

Further, provided are a semiconductor package in which structural stability is increased and a method of fabricating the same.

Further still, provided are a method of fabricating a semiconductor package in which process is simplified and cost is reduced and a semiconductor package fabricated by the same.

According to an aspect of an example embodiment, a semiconductor package includes: a first redistribution substrate; a module structure on the first redistribution substrate; a first molding layer on the first redistribution substrate and surrounding the module structure; and a vertical connection structure on a side of the module structure, the vertical connection structure vertically extending and connected to the first redistribution substrate, wherein the module structure includes: an interposer substrate including a glass substrate, and a first semiconductor chip mounted on the interposer substrate; and a second semiconductor chip mounted on the interposer substrate.

According to an aspect of an example embodiment, a semiconductor package includes: a first redistribution substrate; a connection substrate on the first redistribution substrate, the connection substrate having an opening that penetrates the connection substrate; a module structure on the first redistribution substrate and in the opening of the connection substrate; and a first molding layer on the first redistribution substrate, the first molding layer covering the module structure and the connection substrate, wherein the module structure includes: an interposer substrate; a first semiconductor chip on the interposer substrate; and a second semiconductor chip on the interposer substrate, wherein the interposer substrate includes: a core portion; an upper buildup portion on a top surface of the core portion; and a lower buildup portion on a bottom surface of the core portion, wherein the first semiconductor chip and the second semiconductor chip are electrically connected through the upper buildup portion, and the lower buildup portion directly contacts the first redistribution substrate.

According to an aspect of an example embodiment, a semiconductor package includes: a first redistribution substrate; a second redistribution substrate on the first redistribution substrate; a connection substrate that connects the first redistribution substrate to the second redistribution substrate, the connection substrate having an opening that penetrates the connection substrate; a module structure between the first redistribution substrate and the second redistribution substrate, the module structure being in the opening of the connection substrate; a plurality of external terminals on a bottom surface of the first redistribution substrate; and an upper package mounted on the second redistribution substrate, wherein the module structure includes: an interposer substrate connected to the first redistribution substrate; and a first semiconductor chip on the interposer substrate; and a second semiconductor chip on the interposer substrate and spaced apart from the first semiconductor chip, and a core portion of the interposer substrate and a dielectric pattern of the first redistribution substrate include different materials from each other.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a cross-sectional view showing a semiconductor package according to one or more embodiments of the disclosure;

FIG. 2 illustrates an enlarged view showing section A of FIG. 1;

FIG. 3 illustrates a cross-sectional view showing a semiconductor package according to one or more embodiments of the disclosure;

FIG. 4 illustrates an enlarged view showing section B of FIG. 3;

FIG. 5 illustrates a cross-sectional view showing a semiconductor package according to one or more embodiments of the disclosure;

FIG. 6 illustrates an enlarged view showing section C of FIG. 5;

FIG. 7 illustrates a cross-sectional view showing a semiconductor package according to one or more embodiments of the disclosure;

FIG. 8 illustrates an enlarged view showing section D of FIG. 7;

FIG. 9 illustrates a cross-sectional view showing a semiconductor package according to one or more embodiments of the disclosure;

FIG. 10 illustrates an enlarged view showing section E of FIG. 9;

FIG. 11 illustrates a cross-sectional view showing a semiconductor package according to one or more embodiments of the disclosure;

FIG. 12 illustrates an enlarged view showing section F of FIG. 11;

FIG. 13 illustrates a cross-sectional view showing a semiconductor package according to one or more embodiments of the disclosure;

FIG. 14 illustrates an enlarged view showing section G of FIG. 13;

FIGS. 15 and 16 illustrate cross-sectional views showing a semiconductor package according to one or more embodiments of the disclosure; and

FIGS. 17 to 26 illustrate cross-sectional views showing a method of fabricating a semiconductor package according to one or more embodiments of the disclosure.

### DETAILED DESCRIPTION

The following will now describe a semiconductor package according to the disclosure with reference to the accompanying drawings.

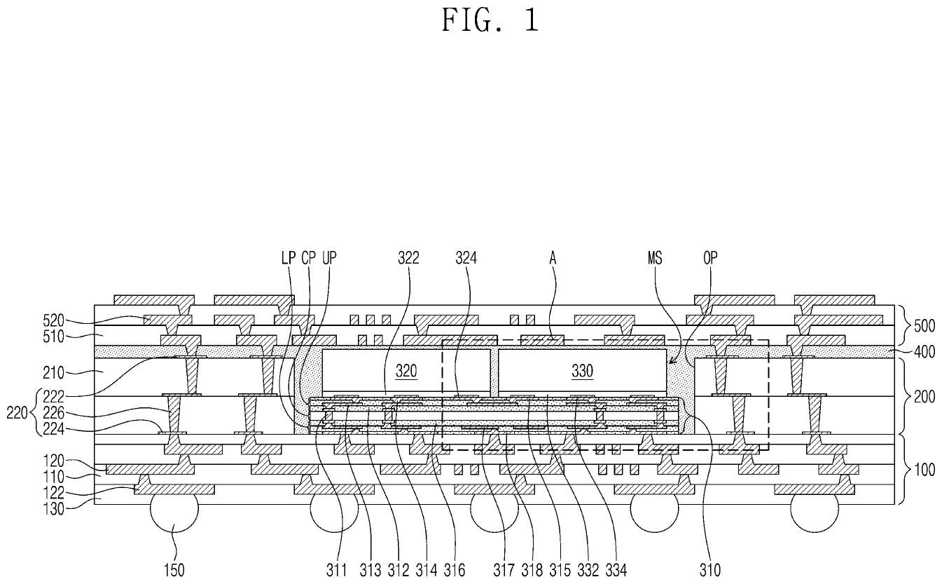

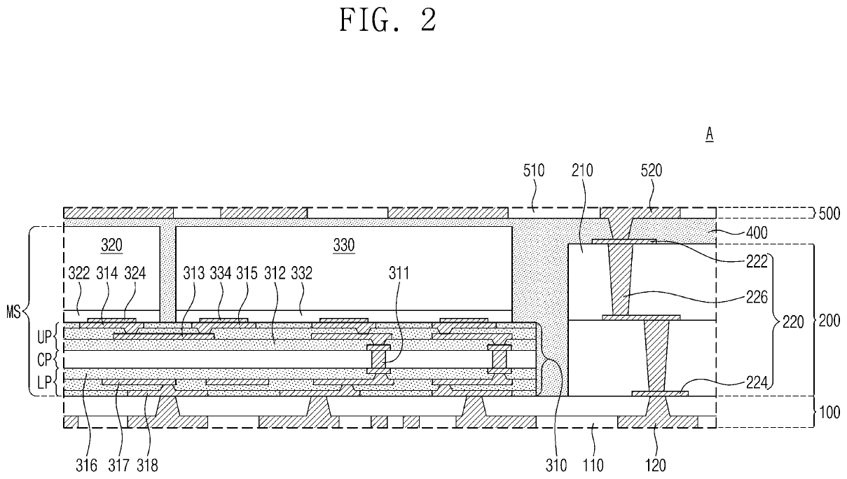

FIG. 1 illustrates a cross-sectional view showing a semiconductor package according to one or more embodiments of the disclosure. FIG. 2 illustrates an enlarged view showing section A of FIG. 1.

Referring to FIGS. 1 and 2, a first redistribution substrate 100 may be provided. The first redistribution substrate 100 may include one first substrate wiring layer or a plurality of first substrate wiring layers that are stacked on each other. Each of the first substrate wiring layers may include a first substrate dielectric pattern 110 and a first substrate wiring pattern 120 in the first substrate dielectric pattern 110. The first substrate wiring pattern 120 in one first substrate wiring layer may be electrically connected to the first substrate wiring pattern 120 in an adjacent first substrate wiring layer. The following will describe an example in which one first substrate wiring layer is used to explain a configuration of the first substrate dielectric pattern 110 and the first substrate wiring pattern 120.

The first substrate dielectric pattern 110 may include a polymer. The first substrate dielectric pattern 110 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers. For example, the first substrate dielectric pattern 110 may include a dielectric material. For example, the first substrate dielectric pattern 110 may include silicon oxide (SiO), silicon nitride (SiN), silicon oxynitride (SiON), or a dielectric polymer.

The first substrate wiring pattern 120 may be provided below the first substrate dielectric pattern 110. The first substrate wiring pattern 120 may horizontally extend below the first substrate dielectric pattern 110. The first substrate wiring pattern 120 may be provided on a bottom surface of the first substrate dielectric pattern 110. The first substrate wiring pattern 120 may protrude onto the bottom surface of the first substrate dielectric pattern 110. Below the first substrate dielectric pattern 110, the first substrate wiring pattern 120 may be covered with another first substrate dielectric pattern 110 that underlies the first substrate wiring pattern 120. The first substrate wiring pattern 120 provided in a lowermost first substrate wiring layer may be substrate pads 122 coupled to external terminals 150 which will be discussed below. As discussed above, the first substrate wiring pattern 120 may be a pad or line part of the first substrate wiring layer. In this sense, the first substrate wiring pattern 120 may be a component for horizontal redistribution in the first redistribution substrate 100. The first substrate wiring pattern 120 may include a conductive material. For example, the first substrate wiring pattern 120 may include metal, such as copper (Cu).

The first substrate wiring pattern 120 may have a damascene structure. For example, the first substrate wiring pattern 120 may have a via that protrudes onto a top surface of first substrate wiring pattern 120. The via may be a component that vertically connects to each other the first substrate wiring patterns 120 of two neighboring first substrate wiring layers. For example, the via may extend from the top surface of the first substrate wiring pattern 120, and may penetrate the first substrate dielectric pattern 110 to be coupled to a bottom surface of the first substrate wiring pattern 120 in another first substrate wiring layer that overlies the via. For example, the via may be a component for connecting the first substrate wiring pattern 120 of an uppermost first substrate wiring layer to a connection substrate 200 or a module structure MS which will be discussed below. For example, the via may extend from the top surface of the first substrate wiring pattern 120, and may penetrate an uppermost first substrate dielectric pattern 110 to be coupled to a connection substrate 200 or a module structure MS which will be discussed. In this configuration, a lower portion of the first substrate wiring pattern 120 positioned on the bottom surface of the first substrate dielectric pattern 110 may be a head part used as a horizontal line or pad, and the via of the first substrate wiring pattern 120 may be a tail part. The first substrate wiring pattern 120 may have an inverse T shape.

A substrate protection layer 130 may be provided. On a bottom surface of the lowermost first substrate wiring layer, the substrate protection layer 130 may cover the substrate pads 122. According to one or more embodiments, the substrate protection layer 130 may expose bottom surfaces of the substrate pads 122, while covering the bottom surface of the lowermost first substrate wiring layer. The substrate protection layer 130 may include a dielectric polymer or a photo-imageable dielectric (PID).

The substrate pads 122 may be provided with external terminals 150 on the bottom surfaces substrate pads 122. For example, the external terminals 150 may penetrate the substrate protection layer 130 to be coupled to the substrate pads 122. The external terminals 150 may include solder balls or solder bumps. Based on type and arrangement of the external terminals 150, a semiconductor package may be provided in the form of a ball grid array (BGA) type, a fine ball-grid array (FBGA) type, or a land grid array (LGA) type.

In the embodiment of FIG. 1, a semiconductor package may be provided in the form of a fan-out panel level package (FO-PLP). For example, a connection substrate 200 may be provided on the first redistribution substrate 100. The connection substrate 200 may have an opening OP that penetrates the connection substrate 200. For example, the opening OP may be shaped like an open hole that connects top and bottom surfaces of the connection substrate 200. The opening OP may be defined to indicate a space (an area) where is provided a module structure MS which will be discussed below. The bottom surface of the connection substrate 200 may be in contact with a top surface of the first redistribution substrate 100. Embodiments of the disclosure, however, are not limited thereto, and when a semiconductor package is fabricated in a chip-last scheme, the bottom surface of the connection substrate 200 may be spaced apart from the top surface of the first redistribution substrate 100. For example, the connection substrate 200 may be connected to the first redistribution substrate 100 through a discrete terminal such as a micro-solder ball. The following description will focus on the embodiment of FIG. 1.

The connection substrate 200 may include a base layer 210 and a conductive member 220 that is a line pattern provided in the base layer 210. The conductive member 220 may have a line structure that vertically connects the first redistribution substrate 100 to a second redistribution substrate 500 which will be discussed below. The conductive member 220 may be disposed between the opening OP and an outer lateral surface of the connection substrate 200. The conductive member 220 may include upper pads 222, lower pads 224, and vias 226. The upper pads 222 may be disposed on the top surface of the connection substrate 200. The upper pads 222 may protrude onto the top surface of the connection substrate 200. Differently from that shown, the upper pads 222 may be buried in the base layer 210, and top surfaces of the upper pads 222 may be coplanar with the top surface of the connection substrate 200. The lower pads 224 may be disposed on the bottom surface of the connection substrate 200. The lower pads 224 may be buried in the base layer 210, and bottom surfaces of the lower pads 224 may be coplanar with the bottom surface of the connection substrate 200. The vias 226 may penetrate the base layer 210, and may electrically connect the upper pads 222 to the lower pads 224. The base layer 210 may include a polymer. For example, the base layer 210 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers. For example, the base layer 210 may include a dielectric material. For example, the base layer 210 may include silicon oxide (SiO), silicon nitride (SiN), silicon oxynitride (SiON), or a dielectric polymer. The upper pads 222, the lower pads 224, and the vias 226 may include a conductor or metal, such as copper (Cu).

The connection substrate 200 may be mounted on the first redistribution substrate 100. For example, the connection substrate 200 may be in contact with the first redistribution substrate 100. The first substrate wiring pattern 120 in the uppermost first substrate wiring layer may penetrate the uppermost first substrate dielectric pattern 110 to be coupled to the lower pads 224. Therefore, the connection substrate 200 may be electrically connected to the external terminal 150 and a module structure MS which will be discussed below.

A module structure MS may be disposed on the first redistribution substrate 100. The module structure MS may be disposed in the opening OP of the connection substrate 200. In this case, the module structure MS may be placed on the first redistribution substrate 100 exposed by the opening OP. The module structure MS may be in contact with the top surface of the first redistribution substrate 100. The module structure MS may be spaced apart from the connection substrate 200. For example, the module structure MS may be spaced apart from an inner lateral surface of the opening OP. The module structure MS may have a top surface at a level from the first redistribution substrate 100 higher than a level of the top surface of the connection substrate 200. For example, the module structure MS may have a height greater than that of the connection substrate 200. In an embodiment, the top surface of the module structure MS may be located at a level from the first redistribution substrate 100 the same as or lower than a level of the top surface of the connection substrate 200. For example, the module structure MS may have a height the same as or less than that of the connection substrate 200. A configuration of the module structure MS will be discussed in detail below.

The module structure MS may include an interposer substrate 310, and may also include a first semiconductor chip 320 and a second semiconductor chip 330 mounted on the interposer substrate 310.

The interposer substrate 310 may include a core portion CP, an upper buildup portion UP, and a lower buildup portion LP.

The core portion CP may extend in one direction. When viewed in plan, the core portion CP may include one core pattern. The present embodiment may exemplarily describe the core portion CP having one core pattern, but embodiments of the disclosure are not limited thereto. According to one or more embodiments, the core portion CP may include two or more core patterns. For example, the interposer substrate 310 may include a plurality of core patterns that are horizontally spaced apart from each other or vertically stacked on each other. The core portion CP may include a dielectric material. For example, the core portion CP may include one of glass plates, glass fibers, ceramic plates, epoxy, and resin. The core portion CP may include glass fiber. In this case, the interposer substrate 310 may be a glass substrate. For example, the core portion CP may include silicon (Si). For another example, the core portion CP may include one selected from stainless steels, aluminum (Al), nickel (Ni), magnesium (Mg), zinc (Zn), tantalum (Ta), and any combination of those materials.

The core portion CP may have a vertical connection terminal 311 that vertically penetrates the core portion CP. The vertical connection terminal 311 may extend from top to bottom surfaces of the core portion CP. A portion of the vertical connection terminal 311 may extend onto the bottom surface of the core portion CP, and another portion of the vertical connection terminal 311 may extend onto the top surface of the core portion CP. The portions of the vertical connection terminal 311 that protrude onto the bottom and top surfaces of the core portion CP may correspond to pads to which the upper buildup portion UP and the lower buildup portion LP are coupled. FIGS. 1 and 2 illustrate that the pad parts of the vertical connection terminal 311 that extend onto the top and bottom surfaces of the core portion CP are components independent of via parts of the vertical connection terminal 311 that penetrate the core portion CP, but embodiments of the disclosure are not limited thereto. The pad part and the via part of the vertical connection terminal 311 may be provided in the form of a single body. In an embodiment, a top surface of the vertical connection terminal 311 may be coplanar with the top surface of the core portion CP, and a bottom surface of the vertical connection terminal 311 may be coplanar with the bottom surface of the vertical connection terminal 311. The vertical connection terminal 311 may be provided in plural. The vertical connection terminals 311 may include a conductive material or a metallic material, such as copper (Cu).

The upper buildup portion UP may cover the top surface of the core portion CP. The upper buildup portion UP may include upper dielectric patterns 312 and upper wiring patterns 313 that are sequentially stacked on the top surface of the core portion CP. The upper wiring patterns 313 may be connected to the vertical connection terminals 311 of the core portion CP. For example, a lowermost one of the upper dielectric patterns 312 may be in contact with the top surface of the core portion CP, and some of the upper wiring patterns 313 may penetrate the lowermost upper dielectric pattern 312 to come into contact with the vertical connection terminals 311. An uppermost one of the upper dielectric patterns 312 may expose some of the upper wiring patterns 313, and the exposed upper wiring patterns 313 may correspond to first interposer pads 314 for mounting the first semiconductor chip 320 on the interposer substrate 310 and to second interposer pads 315 for mounting the second semiconductor chip 330 on the interposer substrate 310.

The lower buildup portion LP may cover the bottom surface of the core portion CP. The lower buildup portion LP may include lower dielectric patterns 316 and lower wiring patterns 317 that are sequentially stacked on the bottom surface of the core portion CP. The lower wiring patterns 317 may be connected to the vertical connection terminals 311. For example, an uppermost one of the lower dielectric patterns 316 may be in contact with the bottom surface of the core portion CP, and some of the lower wiring patterns 317 may penetrate the uppermost lower dielectric pattern 316 to come into contact with the vertical connection terminals 311. Thus, the upper wiring patterns 313 may be electrically connected through the vertical connection terminals 311 to the lower wiring patterns 317. A lowermost one of the lower dielectric patterns 316 may expose some of the lower wiring patterns 317, and the exposed lower wiring patterns 317 may correspond to third interposer pads 318 for coupling the interposer substrate 310 to the first redistribution substrate 100.

The first semiconductor chip 320 and the second semiconductor chip 330 may be mounted on the interposer substrate 310. The first semiconductor chip 320 and the second semiconductor chip 330 may be disposed spaced apart from each other. FIG. 1 depicts that the first semiconductor chip 320 and the second semiconductor chip 330 have the same size, but embodiments of the disclosure are not limited thereto. According to one or more embodiments, the first semiconductor chip 320 and the second semiconductor chip 330 may have different sizes, for example, different heights or widths. The first semiconductor chip 320 and the second semiconductor chip 330 may be of the same or different types.

The first semiconductor chip 320 and the second semiconductor chip 330 may include a semiconductor material, such as silicon (Si). The first semiconductor chip 320 and the second semiconductor chip 330 may each include a first circuit layer 322 and a second circuit layer 332. Each of the first circuit layer 322 and the second circuit layer 332 may include a logic circuit. For example, each of the first semiconductor chip 320 and the second semiconductor chip 330 may be a logic chip. For example, each of the first circuit layer 322 and the second circuit layer 332 may include a memory circuit. For example, each of the first semiconductor chip 320 and the second semiconductor chip 330 may be a memory chip. For example, each of the first circuit layer 322 and the second circuit layer 332 may include a logic circuit, a memory circuit, a passive element, or a combination of those circuits/element. In one or more embodiments of the disclosure, the first circuit layer 322 and the second circuit layer 332 may include various integrated circuits, if necessary. The second semiconductor chip 330 may be provided in plural. In this case, the plurality of second semiconductor chips 330 may have a vertical chip stack structure.

The first semiconductor chip 320 and the second semiconductor chip 330 may be in contact with a top surface of the interposer substrate 310. For example, first chip pads 324 may be provided on one surface of the first circuit layer 322 of the first semiconductor chip 320. Second chip pads 334 may be provided on one surface of the second circuit layer 332 of the second semiconductor chip 330. The first semiconductor chip 320 and the second semiconductor chip 330 may be in contact with the interposer substrate 310. For example, the first circuit layer 322 of the first semiconductor chip 320 and the second circuit layer 332 of the second semiconductor chip 330 may be in contact with the upper buildup portion UP of the interposer substrate 310. The first chip pads 324 may be in contact with the first interposer pads 314. The second chip pads 334 may be in contact with the second interposer pads 315.

The first semiconductor chip 320 may be mounted on the first interposer pads 314. The first chip pads 324 may be directly connected to the first interposer pads 314. For example, an intermetallic bonding may be achieved between the first chip pads 324 and the first interposer pads 314. In this description, the term “hybrid bonding” may denote a bonding in which two components of the same kind are merged at an interface therebetween. For example, a continuous configuration may be provided between the first chip pad 324 and the first interposer pad 314 that are coupled to each other, and an invisible interface may be present between the first chip pad 324 and the first interposer pad 314. The first chip pad 324 and the first interposer pad 314 may be formed of the same material and provided in the form of one component. For example, the first chip pad 324 and the first interposer pad 314 may constitute a single unitary body.

The second semiconductor chip 330 may be mounted on the second interposer pads 315. The second chip pads 334 may be directly connected to the second interposer pads 315. For example, an intermetallic bonding may be achieved between the second chip pads 334 and the second interposer pads 315. A continuous configuration may be provided between the second chip pad 334 and the second interposer pad 315 that are coupled to each other, and an invisible interface may be present between the second chip pad 334 and the second interposer pad 315. The second chip pad 334 and the second interposer pad 315 may be formed of the same material and provided in the form of one component. For example, the second chip pad 334 and the second interposer pad 315 may constitute a single unitary body.

The upper wiring patterns 313 of the upper buildup portion UP may connect at least some of the first interposer pads 314 to at least some of the second interposer pads 315. The first semiconductor chip 320 and the second semiconductor chip 330 may be electrically connected through the upper buildup portion UP. For example, the first interposer pads 314 on which the first semiconductor chip 320 is mounted may be connected through the upper wiring patterns 313 to the second interposer pads 315 on which the second semiconductor chip 330 is mounted. Hence, a chip-to-chip connection may be achieved between the first semiconductor chip 320 and the second semiconductor chip 330. As the first semiconductor chip 320 and the second semiconductor chip 330 are connected through the upper buildup portion UP of the interposer substrate 310 that underlies the first semiconductor chip 320 and the second semiconductor chip 330, a short length of electrical connection may be provided between the first semiconductor chip 320 and the second semiconductor chip 330, and a semiconductor package may increase in electrical properties.

The module structure MS may be connected to the first redistribution substrate 100. A direct bonding method may be used to mount the module structure MS on the first redistribution substrate 100. For example, the third interposer pads 318 of the module structure MS may be provided on a bottom surface of the interposer substrate 310. The interposer substrate 310 of the module structure MS may be in contact with the first redistribution substrate 100, and the module structure MS may be coupled to the first redistribution substrate 100 through the first substrate wiring pattern 120 that penetrates the uppermost first substrate dielectric pattern 110 to be coupled to the third interposer pads 318. Therefore, the module structure MS may be electrically connected to the connection substrate 200 and the external terminals 150.

Embodiments of the disclosure, however, are not limited thereto. The bottom surface of the module structure MS may be spaced apart from the top surface of the first redistribution substrate 100. For example, the module structure MS may be connected to the first redistribution substrate 100 through a terminal, such as a micro-solder ball, separately provided on the third interposer pads 318. The following description will focus on the embodiment of FIG. 1.

According to one or more embodiments of the disclosure, a glass substrate whose strength is high may be used as the interposer substrate 310 for connecting the first semiconductor chip 320 and the second semiconductor chip 330 to each other. Thus, the interposer substrate 310 may suppress warpage of a semiconductor package. As a result, a semiconductor package may have increased structural stability.

A molding layer 400 may be provided on the connection substrate 200. The molding layer 400 may cover the connection substrate 200 and the module structure MS. The molding layer 400 may fill the opening OP of the connection substrate 200. For example, in the opening OP of the connection substrate 200, the molding layer 400 may fill a gap between the connection substrate 200 and the module structure MS. In one or more embodiments, when the module structure MS and the first redistribution substrate 100 are spaced apart from each other, the molding layer 400 may fill a space (an area) between the module structure MS and the first redistribution substrate 100. The molding layer 400 may cover the top surface of the connection substrate 200 and the top surface of the module structure MS. For example, on the interposer substrate 310, the molding layer 400 may cover the first semiconductor chip 320 and the second semiconductor chip 330. In an embodiment, the molding layer 400 may not cover the top surface of the connection substrate 200, for example, any of top surfaces of the first semiconductor chip 320 and the second semiconductor chip 330. The molding layer 400 may include a dielectric polymer material. For example, the molding layer 400 may include an epoxy molding compound (EMC).

In one or more embodiments of the disclosure, as the module structure MS does not have a discrete molding member, the molding layer 400 may be in direct contact with the interposer substrate 310, the first semiconductor chip 320, and the second semiconductor chip 330. As the module structure MS does not have a discrete molding member, the module structure MS may decrease in size. In addition, because the first semiconductor chip 320 and the second semiconductor chip 330 of the module structure MS are buried and protected by the molding layer 400 of a semiconductor package, the first semiconductor chip 320 and the second semiconductor chip 330 may not be exposed to external impact, and any of the module structure MS and a semiconductor package may not decrease in structural stability.

A second redistribution substrate 500 may be provided on the molding layer 400. The second redistribution substrate 500 may include one second substrate wiring layer or a plurality of second substrate wiring layers that are stacked on each other. Each of the second substrate wiring layers may include a second substrate dielectric pattern 510 and a second substrate wiring pattern 520 in the second substrate dielectric pattern 510. The second substrate wiring pattern 520 in one second substrate wiring layer may be electrically connected to the second substrate wiring pattern 520 in an adjacent second substrate wiring layer. The following will describe an example in which one second substrate wiring layer is used to explain a configuration of the second substrate dielectric pattern 510 and the second substrate wiring pattern 520.

The second substrate dielectric pattern 510 may include a polymer. The second substrate dielectric pattern 510 may include a dielectric polymer or a photo-imageable dielectric (PID). For example, the photo-imageable dielectric may include at least one selected from photosensitive polyimide, polybenzoxazole (PBO), phenolic polymers, and benzocyclobutene polymers. For example, the second substrate dielectric pattern 510 may include a dielectric material. For example, the second substrate dielectric pattern 510 may include silicon oxide (SiO), silicon nitride (SiN), silicon oxynitride (SiON), or a dielectric polymer.

The second substrate wiring pattern 520 may be provided on the second substrate dielectric pattern 510. The second substrate wiring pattern 520 may horizontally extend on the second substrate dielectric pattern 510. The second substrate wiring pattern 520 may be provided on a top surface of the second substrate dielectric pattern 510. The second substrate wiring patterns 520 may protrude onto the top surface of the second substrate dielectric pattern 510. On the second substrate dielectric pattern 510, the second substrate wiring pattern 520 may be covered with another second substrate dielectric pattern 510 that overlies the second substrate wiring pattern 520. A lowermost second substrate wiring pattern 520 may be provided on a top surface of the molding layer 400, and on the molding layer 400, may be covered with the second substrate dielectric pattern 510 that overlies the lowermost second substrate wiring pattern 520. The second substrate wiring pattern 520 may be a pad or line part of the second substrate wiring layer. In this sense, the second substrate wiring pattern 520 may be a component for horizontal redistribution in the second redistribution substrate 500. The second substrate wiring pattern 520 may include a conductive material. For example, the second substrate wiring pattern 520 may include copper (Cu). The second substrate wiring pattern 520 of an uppermost second substrate wiring layer may be exposed on a top surface of the second redistribution substrate 500, and may serve as a pad on which an external package or an electronic apparatus is mounted.

The second substrate wiring pattern 520 may have a damascene structure. For example, the second substrate wiring pattern 520 may have a via that protrudes from a bottom surface of second substrate wiring pattern 520. The via may be a component that vertically connects to each other the second substrate wiring patterns 520 of two neighboring second substrate wiring layers. For example, the via may extend from the bottom surface of the second substrate wiring pattern 520, and may penetrate the second substrate dielectric pattern 510 to be coupled to the second substrate wiring pattern 520 of another second substrate wiring layer that underlies the via. For example, the via may connect the lowermost second substrate wiring pattern 520 to the connection substrate 200. For example, the via may extend from the bottom surface of the second substrate wiring pattern 520, and may penetrate the molding layer 400 to be coupled to the upper pads 222 of the connection substrate 200. In this configuration, an upper portion of the second substrate wiring pattern 520 positioned on the top surface of the second substrate dielectric pattern 510 may be a head part used as a horizontal line or pad, and the via of the second substrate wiring pattern 520 may be a tail part. The second substrate wiring pattern 520 may have a T shape.

In the following embodiments, the components described in the embodiments of FIGS. 1 and 2 are allocated with the same reference numerals, and a repetitive explanation of the components having the same reference numerals will be omitted or abridged for convenience of description. The following will focus on differences between the embodiments of FIGS. 1 and 2 and other embodiments described below.

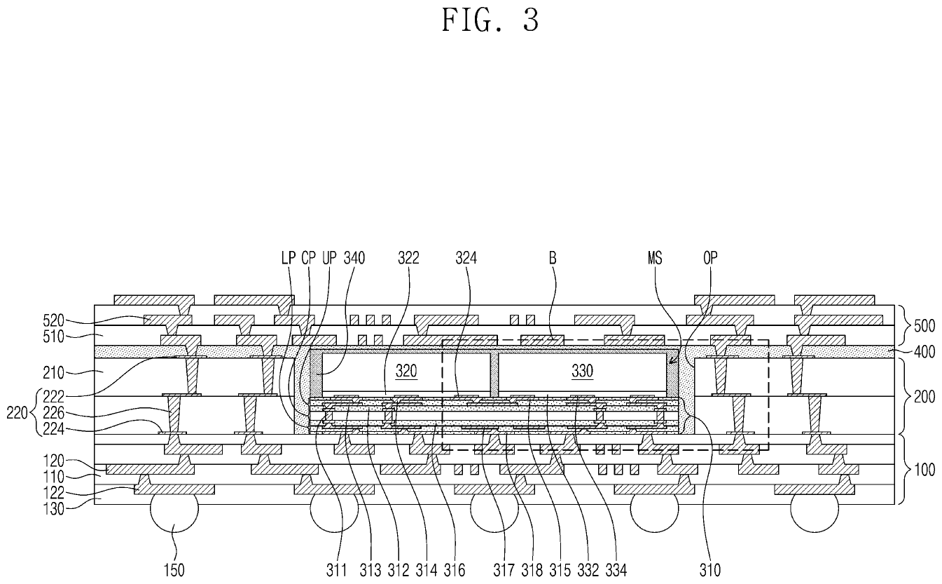

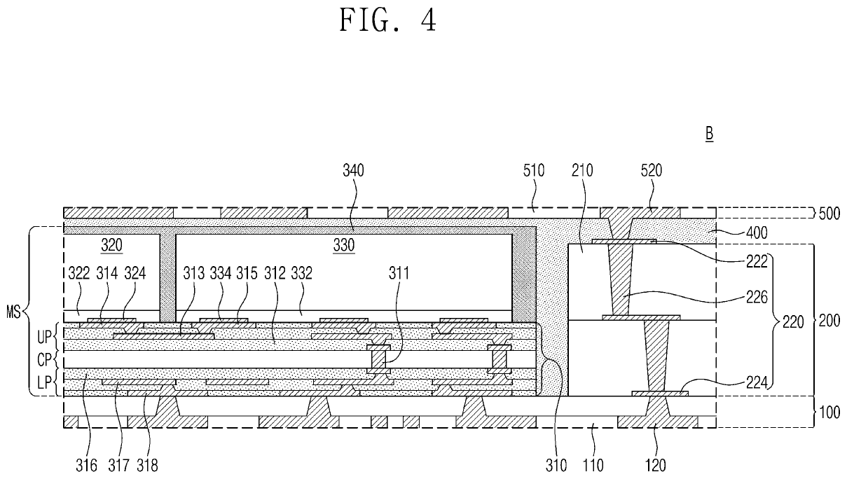

FIG. 3 illustrates a cross-sectional view showing a semiconductor package according to one or more embodiments of the disclosure. FIG. 4 illustrates an enlarged view showing section B of FIG. 3.

Referring to FIGS. 3 and 4, the module structure MS may further include an inner molding layer 340.

The inner molding layer 340 may be provided on the interposer substrate 310. On the interposer substrate 310, the inner molding layer 340 may cover the first semiconductor chip 320 and the second semiconductor chip 330. The inner molding layer 340 may surround the first semiconductor chip 320 and the second semiconductor chip 330. The inner molding layer 340 may have a width the same as that of the interposer substrate 310. For example, the inner molding layer 340 may have lateral surfaces vertically aligned with those of the interposer substrate 310. In this case, the inner molding layer 340 may cover the top surfaces of the first semiconductor chip 320 and the second semiconductor chip 330. In an embodiment, the inner molding layer 340 may expose the top surface of the first semiconductor chip 320 or the top surface of the second semiconductor chip 330. The inner molding layer 340 may include a dielectric polymer material. For example, the inner molding layer 340 may include an epoxy molding compound (EMC).

A molding layer 400 may be provided on the connection substrate 200. The molding layer 400 may cover the connection substrate 200 and the module structure MS. The molding layer 400 may cover the top surface of the connection substrate 200 and the top surface of the module structure MS. For example, the molding layer 400 may surround the interposer substrate 310 and the inner molding layer 340, and may cover a top surface of the inner molding layer 340. In an embodiment, the molding layer 400 may not cover the top surface of the inner molding layer 340.

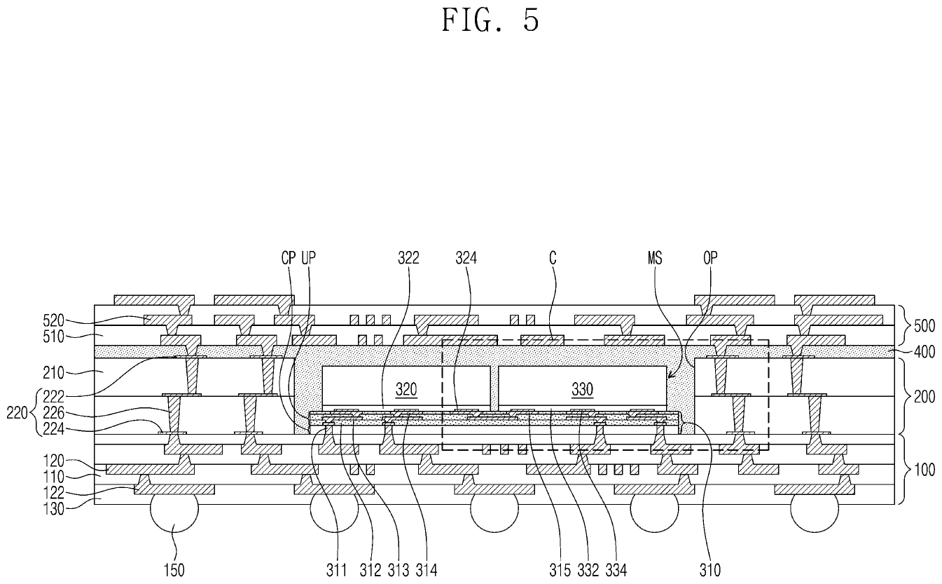

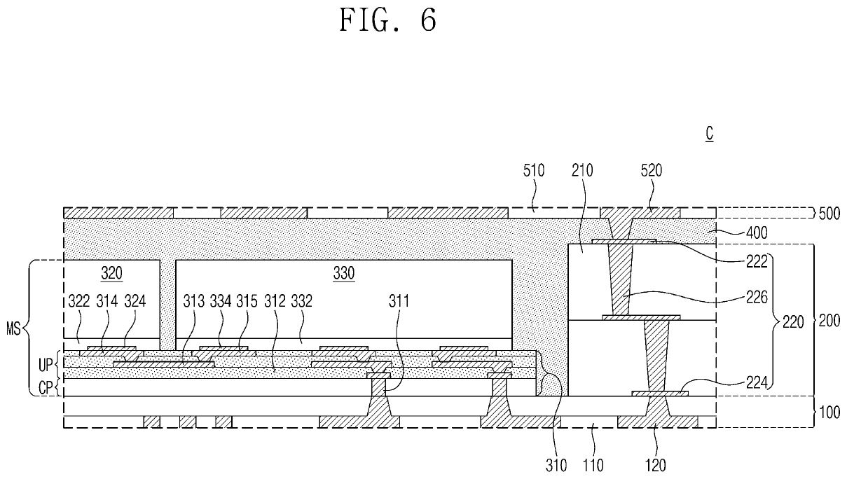

FIG. 5 illustrates a cross-sectional view showing a semiconductor package according to one or more embodiments of the disclosure. FIG. 6 illustrates an enlarged view showing section C of FIG. 5.

Referring to FIGS. 5 and 6, the module structure MS may include an interposer substrate 310, and may also include a first semiconductor chip 320 and a second semiconductor chip 330 that are mounted on the interposer substrate 310.

The interposer substrate 310 may include a core portion CP and an upper buildup portion UP. For example, differently from the embodiment of FIGS. 1 and 2, the interposer substrate 310 may not include the lower buildup portion LP.

The module structure MS may be connected to the first redistribution substrate 100. A direct bonding method may be used to mount the module structure MS on the first redistribution substrate 100. The interposer substrate 310 of the module structure MS may be in contact with the first redistribution substrate 100. For example, the core portion CP of the interposer substrate 310 may be in contact with the top surface of the first redistribution substrate 100. Some of the first substrate wiring patterns 120 of the first redistribution substrate 100 may penetrate the uppermost first substrate dielectric pattern 110 to be coupled to the vertical connection terminals 311 of the core portion CP. Therefore, the module structure MS may be electrically connected to the connection substrate 200 and the external terminals 150.

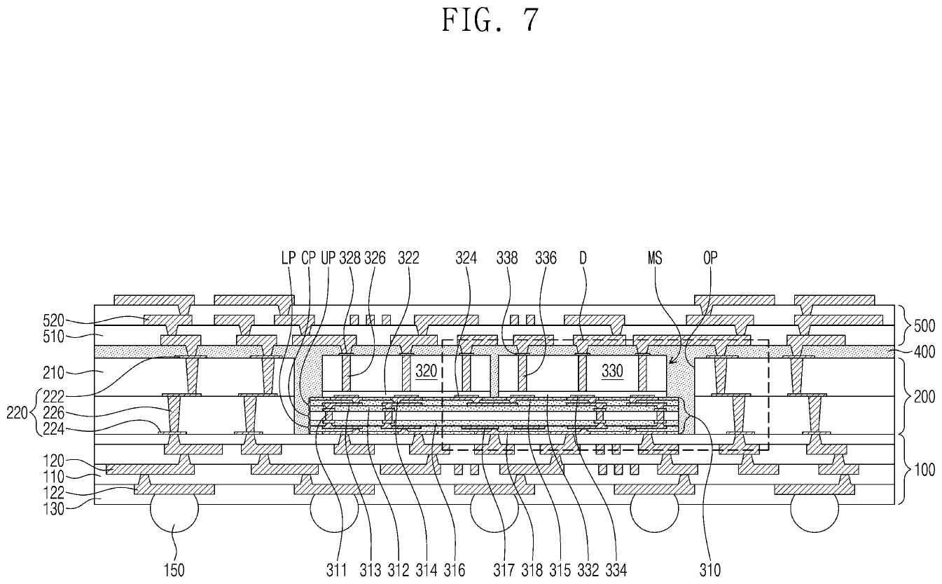

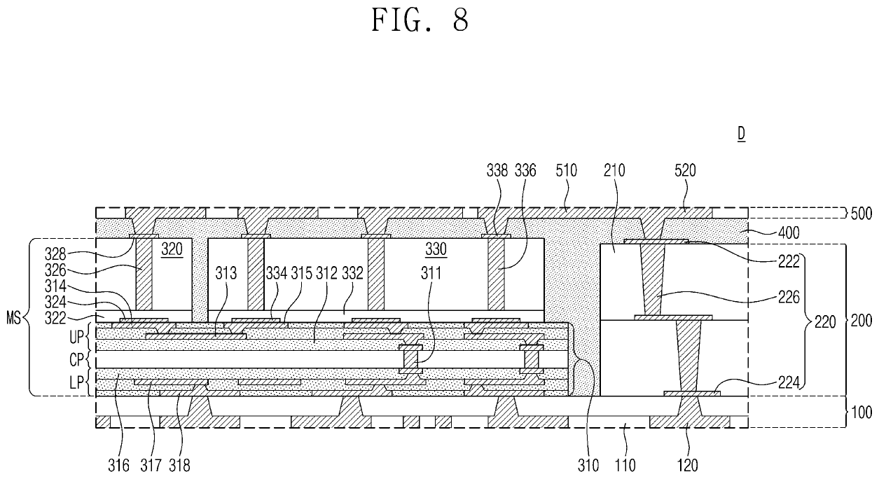

FIG. 7 illustrates a cross-sectional view showing a semiconductor package according to one or more embodiments of the disclosure. FIG. 8 illustrates an enlarged view showing section D of FIG. 7.

Referring to FIGS. 7 and 8, the first semiconductor chip 320 and the second semiconductor chip 330 may further include chip vias. The first semiconductor chip 320 may further include first chip vias 326 that vertically penetrate the first semiconductor chip 320 to be coupled to the first circuit layer 322. The first chip vias 326 may have their ends exposed on the top surface of the first semiconductor chip 320. The second semiconductor chip 330 may further include second chip vias 336 that vertically penetrate the second semiconductor chip 330 to be coupled to the second circuit layer 332. The second chip vias 336 may have their ends exposed on the top surface of the second semiconductor chip 330. The first chip vias 326 and the second chip vias 336 may include a conductive material. For example, the first chip vias 326 and the second chip vias 336 may include a metallic material, such as copper (Cu) or tungsten (W).

The first semiconductor chip 320 and the second semiconductor chip 330 may further include backside pads. The first semiconductor chip 320 may further include first backside pads 328 provided on the top surface of the first semiconductor chip 320 and connected to the first chip vias 326. The second semiconductor chip 330 may further include second backside pads 338 provided on the top surface of the second semiconductor chip 330 and connected to the second chip vias 336.

A molding layer 400 may be provided on the connection substrate 200. The molding layer 400 may cover the connection substrate 200 and the module structure MS.

A second redistribution substrate 500 may be provided on the molding layer 400. The second redistribution substrate 500 may include one second substrate wiring layer or a plurality of second substrate wiring layers that are stacked on each other. Each of the second substrate wiring layers may include a second substrate dielectric pattern 510 and a second substrate wiring pattern 520 in the second substrate dielectric pattern 510. A lowermost second substrate wiring pattern 520 of the second redistribution substrate 500 may extend from a bottom surface of the second substrate wiring pattern 520, and may penetrate the molding layer 400 to be coupled to the upper pads 222 of the connection substrate 200, the first backside pads 328 of the first semiconductor chip 320, and the second backside pads 338 of the second semiconductor chip 330.

According to one or more embodiments of the disclosure, the second redistribution substrate 500 may be electrically connected to the first semiconductor chip 320 and the second semiconductor chip 330 through the first chip vias 326 of the first semiconductor chip 320 and through the second chip vias 336 of the second semiconductor chip 330. Therefore, a short length of electrical connection may be provided between the second redistribution substrate 500 and the first semiconductor chip 320 and the second semiconductor chip 330, and a semiconductor package may increase in electrical properties.

In FIGS. 1 to 8, a hybrid bonding method is used to mount the first semiconductor chip 320 and the second semiconductor chip 330 on the interposer substrate 310, but embodiments of the disclosure are not limited thereto.

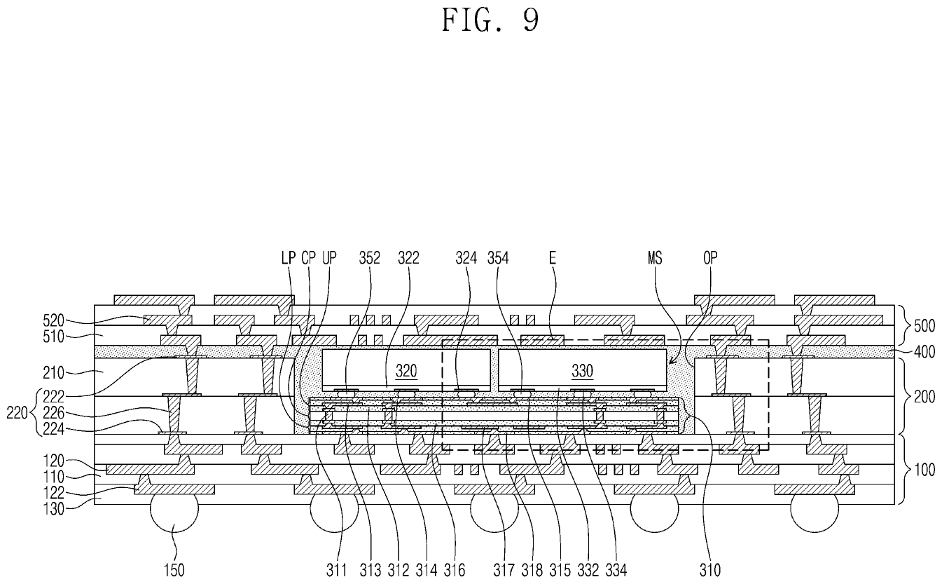

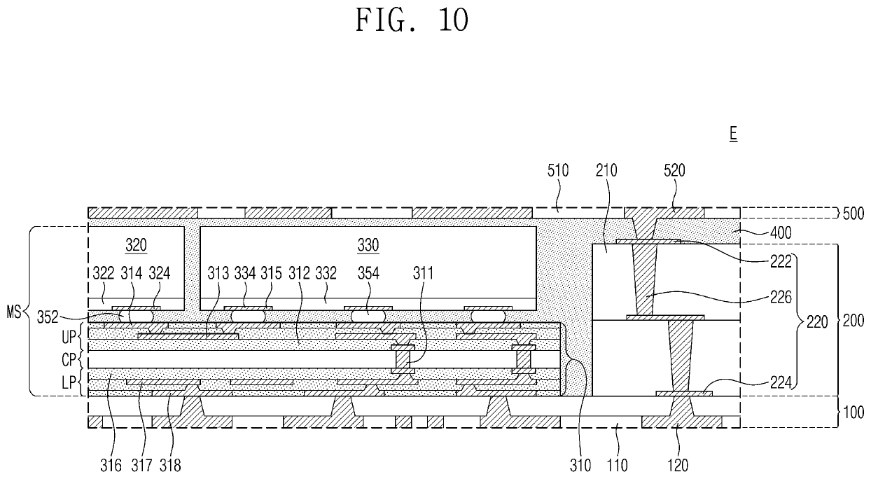

FIG. 9 illustrates a cross-sectional view showing a semiconductor package according to one or more embodiments of the disclosure. FIG. 10 illustrates an enlarged view showing section E of FIG. 9.

Referring to FIGS. 9 and 10, the first semiconductor chip 320 may be mounted on the interposer substrate 310. For example, the first semiconductor chip 320 may be flip-chip mounted on the interposer substrate 310. In this case, the first semiconductor chip 320 may be electrically connected through first connection terminals 352 to the first interposer pads 314 of the interposer substrate 310. The first connection terminals 352 may be provided between the first interposer pads 314 and the first chip pads 324. The first semiconductor chip 320 may be electrically connected to the interposer substrate 310 through the first chip pads 324, the first connection terminals 352, and the first interposer pads 314. As the first semiconductor chip 320 is mounted through the first connection terminals 352, the first semiconductor chip 320 may be spaced apart from the top surface of the interposer substrate 310.

The second semiconductor chip 330 may be mounted on the interposer substrate 310. For example, the second semiconductor chip 330 may be flip-chip mounted on the interposer substrate 310. In this case, the second semiconductor chip 330 may be electrically connected through second connection terminals 354 to the second interposer pads 315 of the interposer substrate 310. The second connection terminals 354 may be provided between the second interposer pads 315 and the second chip pads 334. The second semiconductor chip 330 may be electrically connected to the interposer substrate 310 through the second chip pads 334, the second connection terminals 354, and the second interposer pads 315. As the second semiconductor chip 330 is mounted through the second connection terminals 354, the second semiconductor chip 330 may be spaced apart from the top surface of the interposer substrate 310.

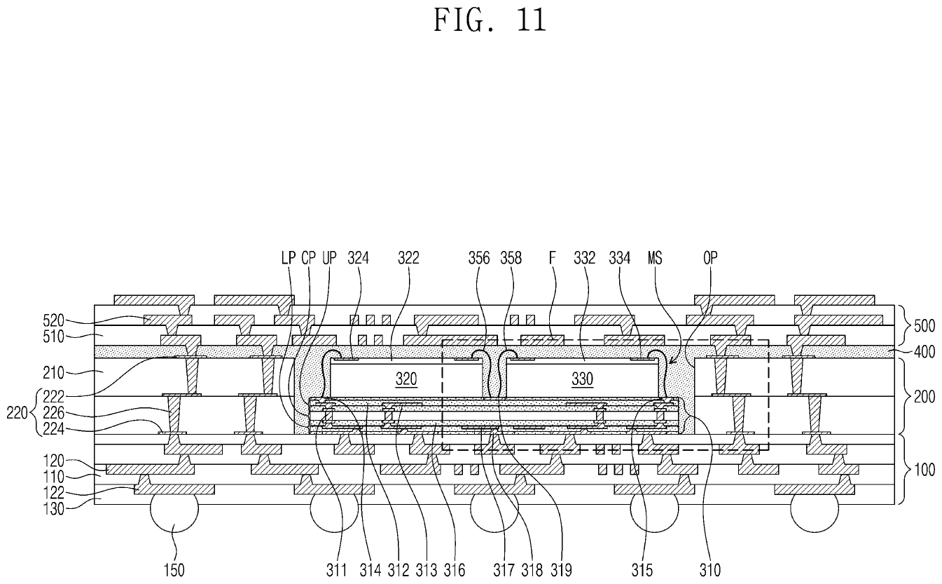

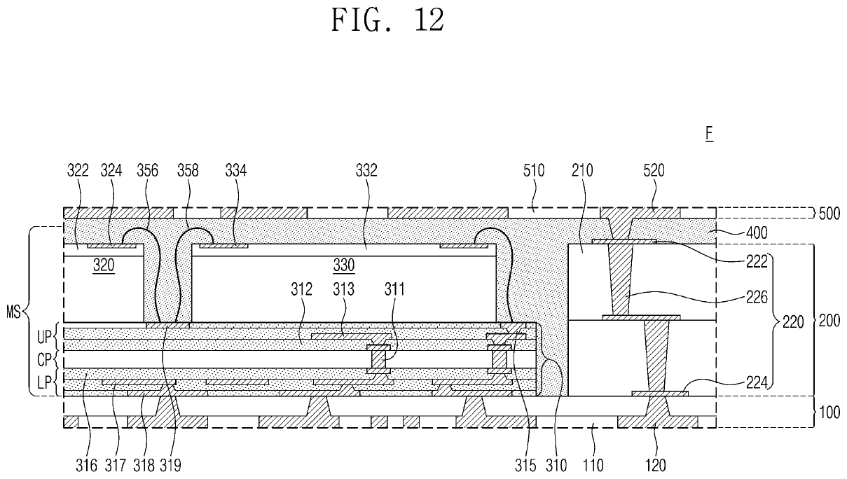

FIG. 11 illustrates a cross-sectional view showing a semiconductor package according to one or more embodiments of the disclosure. FIG. 12 illustrates an enlarged view showing section F of FIG. 11.

Referring to FIGS. 11 and 12, differently from the embodiment of FIGS. 9 and 10, the first semiconductor chip 320 may be wire-bond mounted on the interposer substrate 310. For example, the first semiconductor chip 320 and the second semiconductor chip 330 may be face-up disposed on the interposer substrate 310. In an embodiment, each of the first semiconductor chip 320 and the second semiconductor chip 330 may be attached through an adhesion layer to the top surface of the interposer substrate 310. The first chip pads 324 may be exposed on the top surface of the first semiconductor chip 320, and the second chip pads 334 may be exposed on the top surface of the second semiconductor chip 330.

The first chip pads 324 may be connected through first bonding wires 356 to the first interposer pads 314. For example, each of the first bonding wires 356 may extend from a top surface of one of the first chip pads 324 toward a top surface of one of the first interposer pads 314. The second chip pads 334 may be connected through second bonding wires 358 to the second interposer pads 315. For example, each of the second bonding wires 358 may extend from a top surface of one of the second chip pads 334 toward a top surface of one of the second interposer pads 315. At least one of the first bonding wires 356 of the first semiconductor chip 320 and at least one of the second bonding wires 358 of the second semiconductor chip 330 may be simultaneously coupled to one 319 of the first interposer pad 314 and the second interposer pad 315. Therefore, the first semiconductor chip 320 and the second semiconductor chip 330 may be electrically connected to each other through the first bonding wire 356, the second bonding wire 358, and the interposer pad 319.

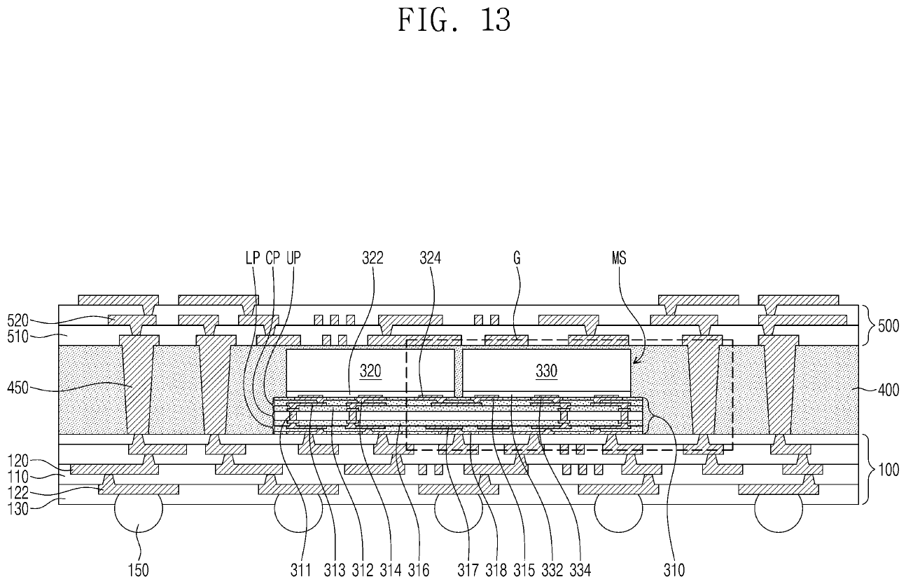

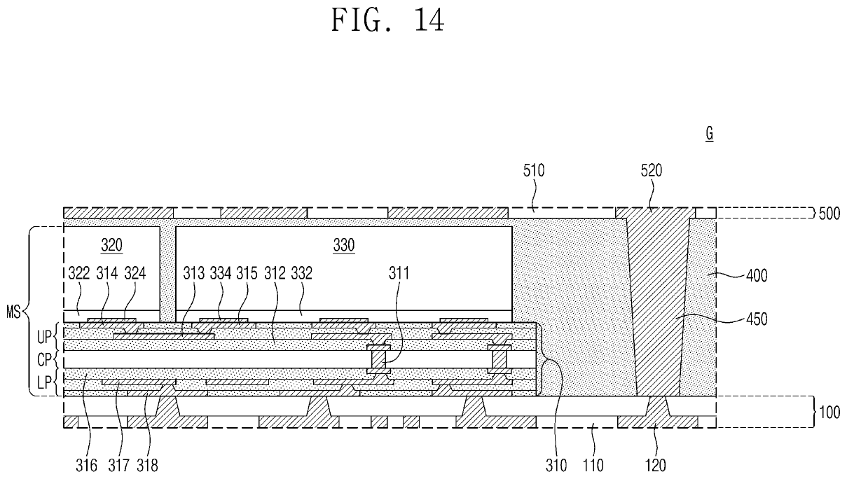

FIG. 13 illustrates a cross-sectional view showing a semiconductor package according to one or more embodiments of the disclosure. FIG. 14 illustrates an enlarged view showing section G of FIG. 13.

In comparison with the semiconductor packages of FIGS. 1 to 12, a semiconductor package may not include the connection substrate 200.

Referring to FIGS. 13 and 14, the molding layer 400 may fill a space (an area) between the first redistribution substrate 100 and the second redistribution substrate 500. On the first redistribution substrate 100, the molding layer 400 may bury the module structure MS. For example, the molding layer 400 may surround the module structure MS and may cover the top surface of the module structure MS. In this case, the module structure MS may be in contact with the first redistribution substrate 100 and may be directly bonded to the first redistribution substrate 100.

A semiconductor package may include a through electrode 450. The through electrode 450 may be disposed laterally spaced apart from the module structure MS. The through electrode 450 may be disposed between the module structure MS and an outer lateral surface of the molding layer 400. The through electrode 450 may vertically penetrate the molding layer 400. The through electrode 450 may be coupled to an uppermost first substrate wiring pattern 120 of the first redistribution substrate 100. For example, a portion of the uppermost first substrate wiring pattern 120 may penetrate the uppermost first substrate dielectric pattern 110 to be coupled to a bottom surface of the through electrode 450. The through electrode 450 may be electrically connected through the first redistribution substrate 100 to the external terminals 150 or the module structure MS. The through electrode 450 may be coupled to the second substrate wiring pattern 520 of the second redistribution substrate 500. The through electrode 450 may include a metal pillar. The through electrode 450 may have a width that increases in a direction from the first redistribution substrate 100 toward the second redistribution substrate 500. The through electrode 450 may be provided in plural.

In the embodiment of FIGS. 13 and 14, the through electrode 450 and the lowermost second substrate wiring pattern 520 of the second redistribution substrate 500 may be connected to constitute a single unitary body. For example, the through electrode 450 may be formed concurrently when the lowermost second substrate wiring pattern 520 is formed. In an embodiment, the through electrode 450 may be provided as a component that is provided separately from the lowermost second substrate wiring pattern 520.

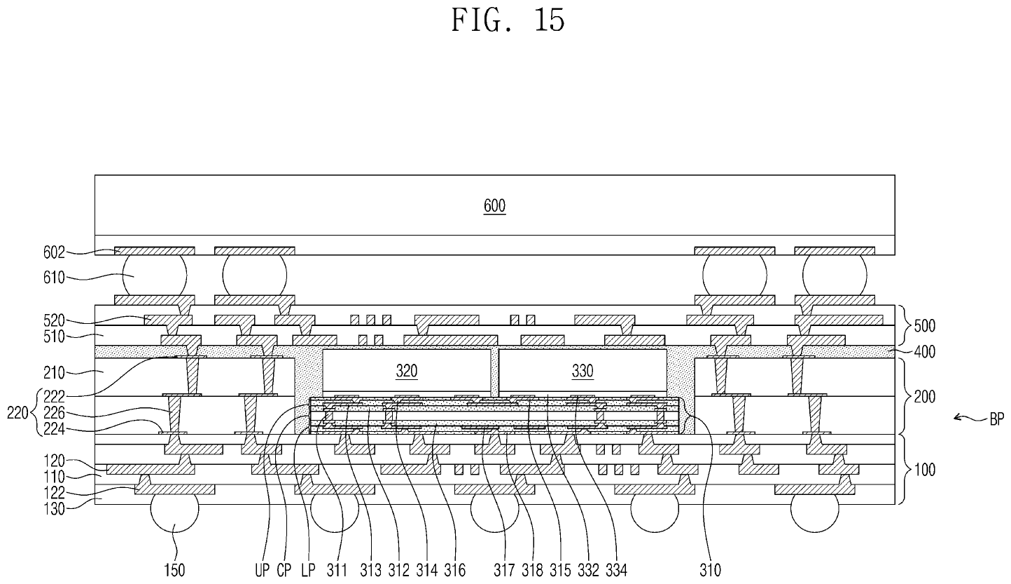

FIG. 15 illustrates a cross-sectional view showing a semiconductor package according to one or more embodiments of the disclosure.

Referring to FIG. 15, a semiconductor package may include a lower package BP and an upper semiconductor chip 600.

The lower package BP may be the same as or similar to one of the semiconductor packages discussed with reference to FIGS. 1 to 14. For example, the lower package BP may include a first redistribution substrate 100, a connection substrate 200 mounted on the first redistribution substrate 100, a module structure MS on the first redistribution substrate 100 and in an opening OP of the connection substrate 200, a molding layer 400 that is provided on the first redistribution substrate 100 and covers the module structure MS, and a second redistribution substrate 500 on the molding layer 400. In an embodiment, the lower package BP may include a first redistribution substrate 100, a module structure MS mounted on the first redistribution substrate 100, a molding layer 400 that is provided on the first redistribution substrate 100 and covers the module structure MS, a second redistribution substrate 500 on the module structure MS, and a through electrode (see 450 of FIGS. 14 and 15) that is provided on a side of the module structure MS and connects the first redistribution substrate 100 to the second redistribution substrate 500.

The upper semiconductor chip 600 may include integrated circuits, and the integrated circuits may include a memory circuit, a logic circuit, or a combination of those circuits. The upper semiconductor chip 600 may be a semiconductor chip whose type is different from that of the first semiconductor chip 320 and the second semiconductor chip 330. For example, the upper semiconductor chip 600 may be a memory chip. FIG. 15 depicts that one upper semiconductor chip 600 is provided on one lower package BP, but embodiments of the disclosure are not limited thereto. According to one or more embodiments, the lower package BP may be provided thereon with a plurality of stacked upper semiconductor chips 600, such as high bandwidth memory (HBM) devices. In an embodiment, the lower package BP may be provided thereon with a plurality of upper semiconductor chips 600 that are horizontally spaced apart from each other.

Upper chip terminals 610 may be disposed between the lower package BP and the upper semiconductor chip 600. The upper chip terminals 610 may be interposed between upper chip pads 602 of the upper semiconductor chip 600 and an uppermost second substrate wiring pattern 520 of the second redistribution substrate 500, and may be electrically connected to the second substrate wiring pattern 520 and the upper chip pads 602. Therefore, the upper semiconductor chip 600 may be electrically connected through the upper chip terminals 610, the second redistribution substrate 500, and the first redistribution substrate 100 to the external terminals 150 and the first semiconductor chip 320 and the second semiconductor chip 330 of the module structure MS.

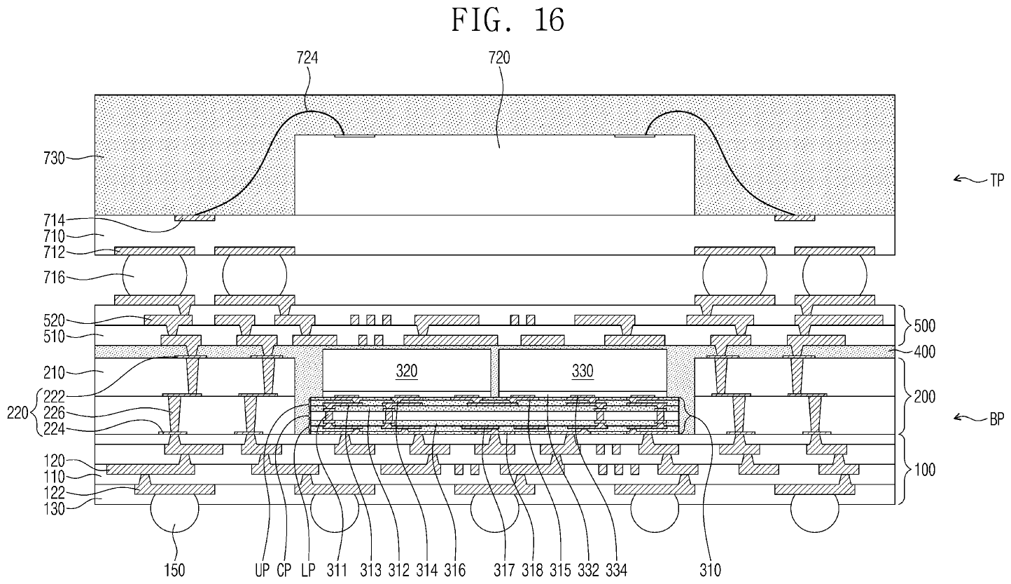

FIG. 16 illustrates a cross-sectional view showing a semiconductor package according to one or more embodiments of the disclosure.

Referring to FIG. 16, a semiconductor package may include a lower package BP and an upper package TP. For example, the semiconductor package may be a package-on-package (POP) in which the upper package TP is mounted on the lower package BP.

The lower package BP may be the same as or similar to one of the semiconductor packages discussed with reference to FIGS. 1 to 14. For example, the lower package BP may include a first redistribution substrate 100, a connection substrate 200 mounted on the first redistribution substrate 100, a module structure MS on the first redistribution substrate 100 and in an opening OP of the connection substrate 200, a molding layer 400 that is provided on the first redistribution substrate 100 and covers the module structure MS, and a second redistribution substrate 500 on the molding layer 400. In an embodiment, the lower package BP may include a first redistribution substrate 100, a module structure MS mounted on the first redistribution substrate 100, a molding layer 400 that is provided on the first redistribution substrate 100 and covers the module structure MS, a second redistribution substrate 500 on the module structure MS, and a through electrode (see 450 of FIGS. 14 and 15) that is provided on a side of the module structure MS and connects the first redistribution substrate 100 to the second redistribution substrate 500.

The upper package TP may be mounted on the lower package BP. The upper package TP may include an upper package substrate 710, an upper package chip 720, and an upper molding layer 730.

The upper package substrate 710 may be a printed circuit board (PCB). For example, the upper package substrate 710 may be a redistribution substrate. The upper package substrate 710 may have first upper substrate pads 712 disposed on a bottom surface of the upper package substrate 710. The upper package substrate 710 may have second upper substrate pads 714 disposed on a top surface of upper package substrate 710.

The upper package chip 720 may be disposed on the upper package substrate 710. The upper package chip 720 may include integrated circuits, and the integrated circuits may include a memory circuit, a logic circuit, or a combination of those circuits. The upper package chip 720 may be a semiconductor chip whose type is different from that of the first semiconductor chip 320 and the second semiconductor chip 330. For example, the upper package chip 720 may be a memory chip. An upper chip pad 722 of the upper package chip 720 may be electrically connected through a bonding wire 724 to the second upper substrate pads 714 of the upper package substrate 710. FIG. 16 depicts that the upper package chip 720 is mounted in a wire bonding method, but the upper package chip 720 may be mounted in various ways.

The upper package substrate 710 may be provided thereon with the upper molding layer 730 that covers the upper package chip 720. The upper molding layer 730 may include a dielectric polymer, such as an epoxy-based polymer.

Conductive terminals 716 may be disposed between the lower package BP and the upper package TP. The conductive terminals 716 may be interposed between an uppermost second substrate wiring pattern 520 of the second redistribution substrate 500 and the first upper substrate pads 712 of the upper package substrate 710, and may be electrically connected to the second substrate wiring pattern 520 and the first upper substrate pads 712. Therefore, the upper package TP may be electrically connected through the conductive terminals 716, the second redistribution substrate 500, and the first redistribution substrate 100 to the external terminals 150 and the first semiconductor chip 320 and the second semiconductor chip 330 of the module structure MS.

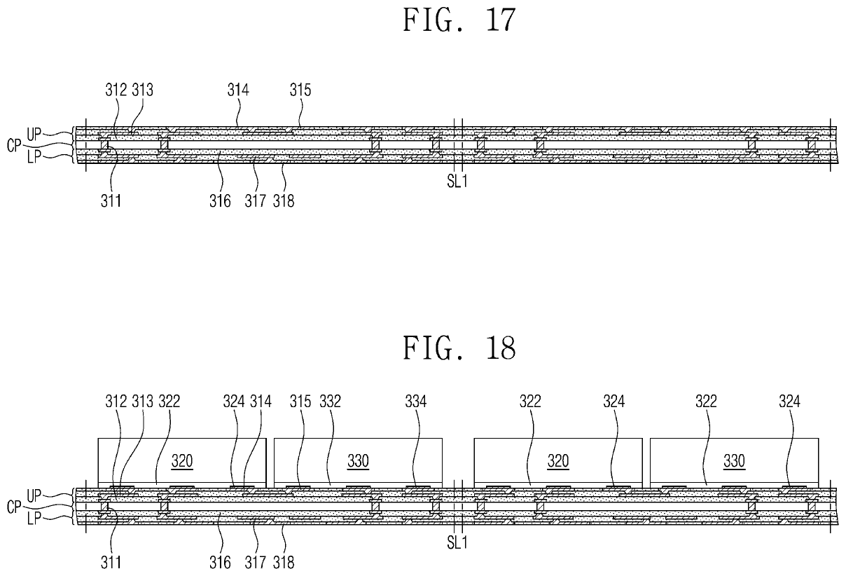

FIGS. 17 to 26 illustrate cross-sectional views showing a method of fabricating a semiconductor package according to one or more embodiments of the disclosure. FIGS. 17 to 21 depict a method of forming a module structure, and FIGS. 22 to 26 depict that a module structure and a connection substrate are used to form a semiconductor package.

Referring to FIG. 17, a core portion CP may be provided. Vertical connection terminals 311 may be formed which are connected to the core portion CP. For example, the vertical connection terminals 311 may be formed by forming holes that penetrate the core portion CP, and then filling the holes with a conductive material.

A lower buildup portion LP may be formed on the core portion CP. For example, a dielectric layer may be formed on a top surface of the core portion CP, and then the dielectric layer may be patterned to form one lower dielectric pattern 316. A conductive layer may be formed on the lower dielectric pattern 316, and then the conductive layer may be patterned to form one lower wiring pattern 317. The process for forming the lower dielectric pattern 316 and the lower wiring pattern 317 may be repeatedly performed. A plurality of lower dielectric patterns 316 and a plurality of lower wiring patterns 317 may constitute the lower buildup portion LP discussed with reference to FIG. 1.

A resultant structure may be turned upside down. Therefore, the lower buildup portion LP may be disposed below the core portion CP.

An upper buildup portion UP may be formed on the core portion CP. For example, a dielectric layer may be formed on a top surface of the core portion CP, and then the dielectric layer may be patterned to form one upper dielectric pattern 312. A conductive layer may be formed on the upper dielectric pattern 312, and then the conductive layer may be patterned to form one upper wiring pattern 313. The process for forming the upper dielectric pattern 312 and the upper wiring pattern 313 may be repeatedly performed. A plurality of upper dielectric patterns 312 and a plurality of upper wiring patterns 313 may constitute the upper buildup portion UP discussed with reference to FIG. 1.

Referring to FIG. 18, first semiconductor chips 320 and second semiconductor chips 330 may be coupled onto the upper buildup portion UP. The first semiconductor chips 320 and the second semiconductor chips 330 may be substantially the same as or similar to the first semiconductor chip 320 and the second semiconductor chip 330, respectively, which are discussed with reference to FIGS. 1 to 16. For example, each of the first semiconductor chips 320 may include a first circuit layer 322 and first chip pads 324. Each of the second semiconductor chips 330 may include a second circuit layer 332 and second chip pads 334.

The first semiconductor chip 320 and the second semiconductor chip 330 may be mounted on first interposer pad 314 and the second interposer pad 315. The first semiconductor chip 320 and the second semiconductor chip 330 may be aligned on an interposer substrate 310 to allow the first chip pads 324 to reside on first interposer pads 314 of the interposer substrate 310 and also to allow the second chip pads 334 to reside on second interposer pads 315 of the interposer substrate 310. The first semiconductor chips 320 may be disposed on the interposer substrate 310 to allow the first chip pads 324 to contact the first interposer pads 314. The second semiconductor chips 330 may be disposed on the interposer substrate 310 to allow the second chip pads 334 to contact the second interposer pads 315. An annealing process may be performed on the first semiconductor chip 320 and the second semiconductor chip 330. In the annealing process, the first chip pads 324 may be coupled to the first interposer pads 314, and the second chip pads 334 may be coupled to the second interposer pads 315. For example, the first chip pad 324 and the first interposer pad 314 may be bonded to form a single unitary body, and the second chip pad 334 and the second interposer pad 315 may be bonded to form a single unitary body. The bonding between the first chip pad 324 and the first interposer pad 314 may be executed automatically, and the bonding between the second chip pad 334 and the second interposer pad 315 may be executed automatically. For example, the first chip pad 324 and the first interposer pad 314 may be formed of the same material (e.g., copper (Cu)), and may be bonded to each other by an intermetallic hybrid bonding process resulting from surface activation at an interface between the first chip pad 324 and the first interposer pad 314 that are in contact with each other, and this may hold true for the second chip pad 334 and the second interposer pad 315.

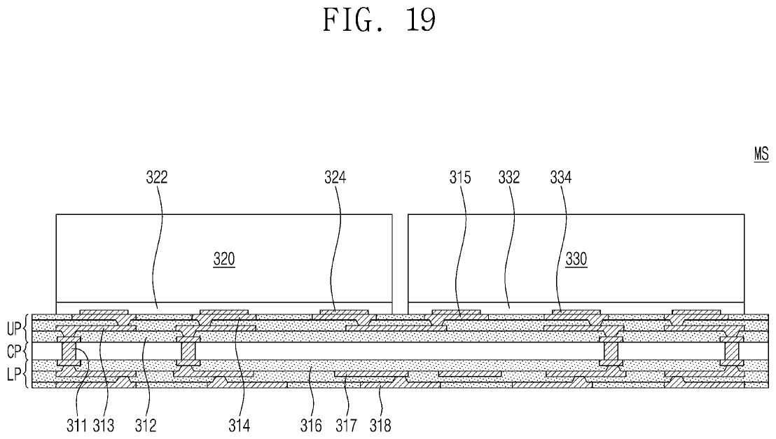

Referring again to FIG. 19, a singulation process, such as a sawing process, may be performed to form module structures MS. For example, the sawing process may be executed along a first sawing line SL1. The upper buildup portion UP, the core portion CP, and the lower buildup portion LP may be diced to form interposer substrates 310, and the module structures MS may be separated from each other in which the first semiconductor chip 320 and the second semiconductor chip 330 are mounted on the interposer substrates 310.

According to one or more embodiments of the disclosure, a discrete process may be performed to form the module structure MS having a structure in which the first semiconductor chip 320 and the second semiconductor chip 330 are connected to each other. For example, a process for forming the module structure MS may be performed separately from a subsequent process for forming a connection substrate 200 and a subsequent process for embedding the module structure MS into the connection substrate 200, and the process for forming the module structure may be variously changed if necessary. Thus, the module structure MS may become modularized, and there may be provided a method of fabricating a semiconductor package whose process is simplified and whose manufacturing cost is reduced.

According to one or more embodiments, module structures MS including an inner molding layer 340 may be formed.

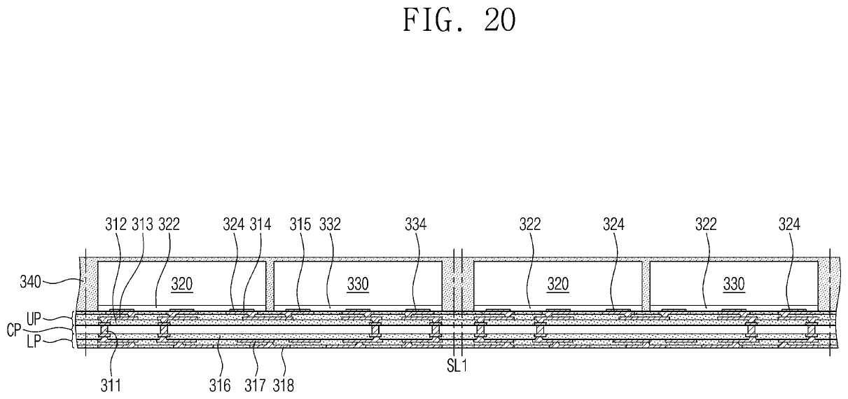

Referring to FIG. 20, on a resultant structure of FIG. 18, an inner molding layer 340 may be formed on the upper buildup portion UP. For example, a dielectric material may be coated on a top surface of the upper buildup portion UP to surround the first semiconductor chips 320 and the second semiconductor chips 330, and then the dielectric material may be cured to form the inner molding layer 340. The dielectric material may include a dielectric polymer or a thermosetting resin.

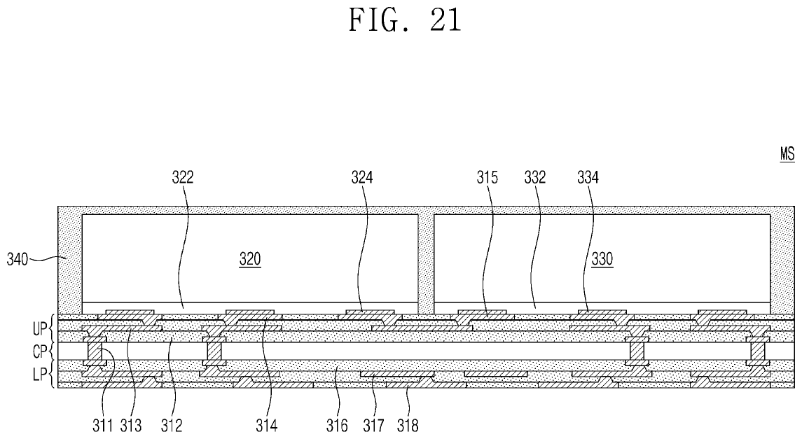

Referring to FIG. 21, a singulation process, such as a sawing process, may be performed to form module structures MS. For example, the sawing process may be executed along a first sawing line SL1. The inner molding layer 340, the upper buildup portion UP, the core portion CP, and the lower buildup portion LP may be diced. Therefore, the module structures MS may be separated from each other in which the first semiconductor chip 320 and the second semiconductor chip 330 are mounted on the interposer substrates 310. In this case, it may be possible to fabricate a semiconductor package discussed with reference to FIGS. 3 and 4. The following description will focus on the embodiment of FIG. 19.

Referring to FIG. 22, a connection substrate 200 may be provided. The connection substrate 200 may be the same as or similar to the connection substrate 200 discussed with reference to FIGS. 1 to 12. For example, the connection substrate 200 may include a base layer 210 and a conductive member 220. The conductive member 220 may include upper pads 222, lower pads 224, and vias 226.

A carrier substrate 900 may be attached to a bottom surface of the connection substrate 200. The carrier substrate 900 may be a dielectric substrate including glass or polymer, or may be a conductive substrate including metal. The carrier substrate 900 may be attached to the lower pads 224 and the base layer 210 of the connection substrate 200 through an adhesive member provided on a top surface of the carrier substrate 900. For example, the adhesive member may include a glue tape.

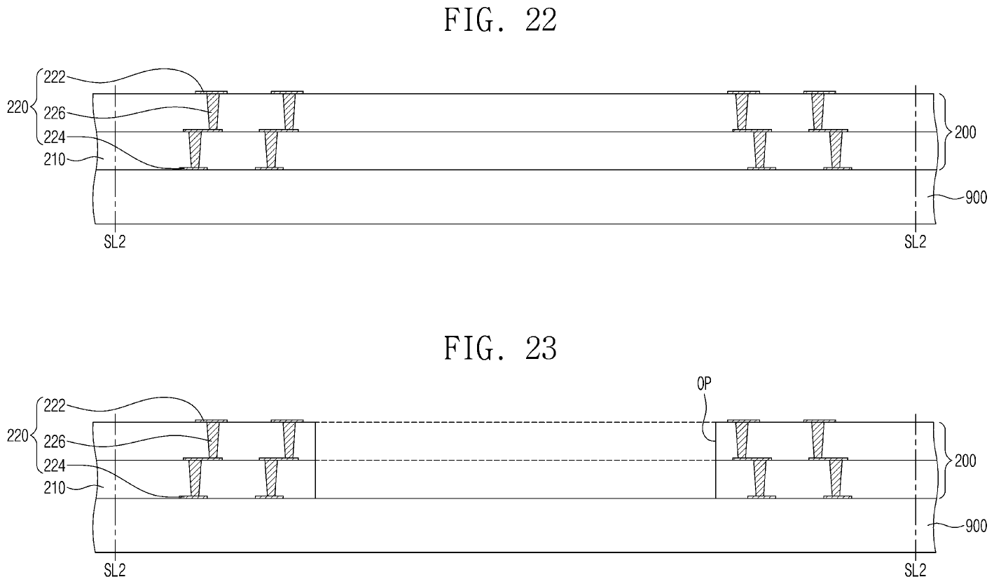

Referring to FIG. 23, an opening OP may be formed in the connection substrate 200. A portion of the connection substrate 200 may be removed to form the opening OP to penetrate the connection substrate 200. The opening OP may be formed by, for example, an etching process such as drilling, laser ablation, or laser cutting. The removed portion of the connection substrate 200 may be a zone in which a module structure MS is provided in a subsequent process.

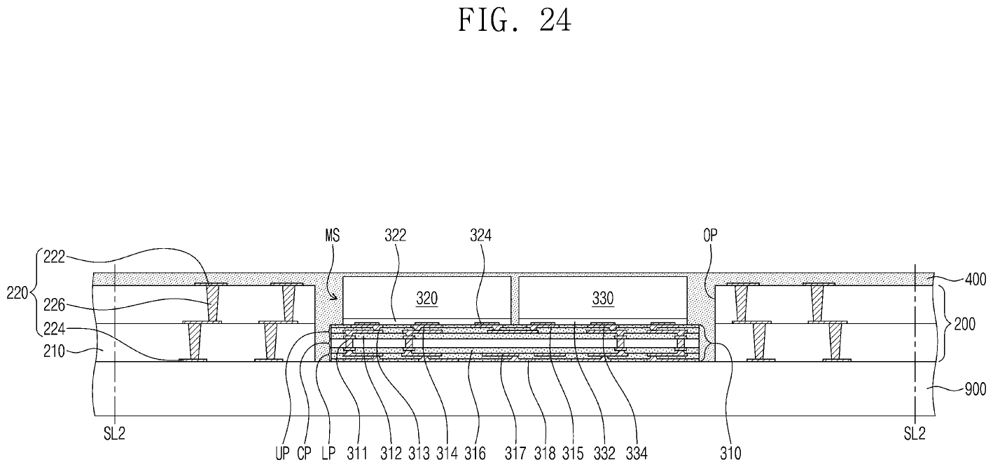

Referring to FIG. 24, a module structure MS may be provided on the carrier substrate 900. The module structure MS may be disposed in the opening OP of the connection substrate 200. The module structure MS may be attached to the carrier substrate 900. In this stage, the module structure MS may be attached to the carrier substrate 900 to allow the interposer substrate 310 to face the carrier substrate 900.

A molding layer 400 may be formed on the carrier substrate 900. The molding layer 400 may fill a space (an area) between the connection substrate 200 and the module structure MS. For example, a dielectric member may be injected into a space (an area) between the connection substrate 200 and the module structure MS, and then the dielectric member may be cured to form the molding layer 400. According to one or more embodiments, the dielectric member may be formed to cover the module structure MS. Therefore, the first semiconductor chip 320 and the second semiconductor chip 330 of the module structure MS may not be exposed. In an embodiment, a portion of the dielectric member may be provided to cover a top surface of the connection substrate 200. Thus, the upper pads 222 of the connection substrate 200 may not be exposed. In an embodiment, the molding layer 400 may be formed not to cover the top surface of the connection substrate 200.

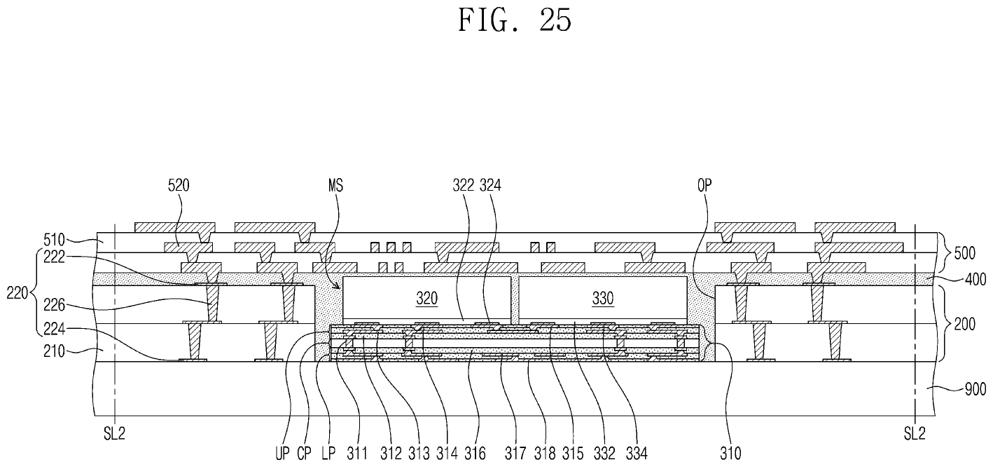

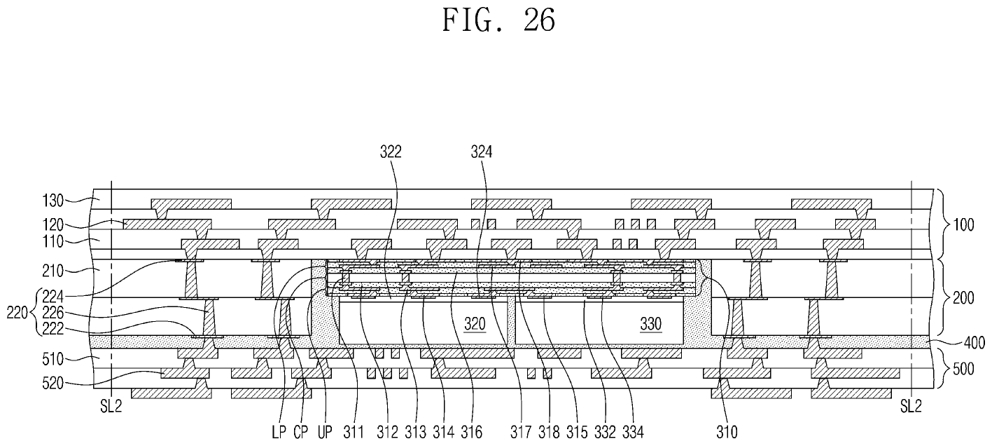

Referring to FIG. 25, a second redistribution substrate 500 may be formed on the connection substrate 200 and the module structure MS. For example, the molding layer 400 may be patterned to expose the upper pads 222 of the connection substrate 200. A conductive layer may be formed on a top surface of the molding layer 400, and the conductive layer may be patterned to form a second substrate wiring pattern 520. A dielectric layer may be formed to cover the second substrate wiring pattern 520 on the top surface of the molding layer 400, the dielectric layer may be patterned to form a second substrate dielectric pattern 510, a conductive layer may be formed on the second substrate dielectric pattern 510, and the conductive layer may be patterned to form a second substrate wiring pattern 520, with the result that one second substrate wiring layer may be formed. The formation of the second substrate wiring layer may be repeatedly performed to form the second redistribution substrate 500.

Referring to FIG. 26, a resultant structure of FIG. 25 may be overturned. Thus, the carrier substrate 900 may be positioned above the connection substrate 200 and the module structure MS.

The carrier substrate 900 may be removed. Therefore, a bottom surface of the connection substrate 200 may be exposed, and likewise a bottom surface of the module structure MS may be exposed. For example, the lower pads 224 of the connection substrate 200 may be exposed, and third interposer pads 318 of the lower buildup portion LP of the interposer substrate 310 may be exposed.

A first redistribution substrate 100 may be formed on the connection substrate 200 and the module structure MS. For example, a dielectric layer may be formed on a top surface of the connection substrate 200 and a top surface of the module structure MS, the dielectric layer may be patterned to form a first substrate dielectric pattern 110, a conductive layer may be formed on the first substrate dielectric pattern 110, and the conductive layer may be patterned to form a first substrate wiring pattern 120, with the result that one first substrate wiring layer may be formed. The formation of the first substrate wiring layer may be repeatedly performed to form the first redistribution substrate 100. The first substrate wiring pattern 120 provided in an uppermost first substrate wiring layer may be substrate pads 122. Afterwards, a substrate protection layer 130 covering the substrate pads 122 may be formed on the first substrate wiring layers.

Referring back to FIG. 1, the substrate protection layer 130 may be patterned to expose the substrate pads 122. External terminals 150 may be attached onto the substrate pads 122.

In a semiconductor package according to one or more embodiments of the disclosure, as semiconductor chips are connected through an upper buildup portion of an interposer substrate that underlies the semiconductor chips, a short length of electrical connection may be provided between the semiconductor chips, and a semiconductor package may increase in electrical properties. In addition, a glass substrate whose strength is high may be adopted as the interposer substrate for connecting the semiconductor chips. Therefore, the interposer substrate may suppress warpage of a semiconductor package. As a result, a semiconductor package may have increased structural stability. Moreover, a module structure may not have a discrete molding member only for the module structure, the module structure may decrease in size. Furthermore, as the semiconductor chips of the module structure are buried and covered with a molding layer of a semiconductor package, the semiconductor chips may not be exposed to external impact, and any of the module structure and the semiconductor package may not decrease in structural stability.

According to one or more embodiments of the disclosure, a process for forming a module structure may be performed separately from a subsequent process for forming a connection substrate and a subsequent process for embedding the module structure into the connection substrate, and the process for forming the module structure may be variously changed if necessary. Thus, the module structure may become modularized, and there may be provided a method of fabricating a semiconductor package whose process is simplified and whose manufacturing cost is reduced.

Although certain embodiments of the disclosure have been described and shown, it will be understood by one of ordinary skill in the art that variations in form and detail may be made therein without departing from the spirit and essential features of the disclosure. The above disclosed embodiments should thus be considered illustrative and not restrictive.

1. A semiconductor package comprising:
a first redistribution substrate;
a module structure on the first redistribution substrate;
a first molding layer on the first redistribution substrate and surrounding the module structure; and
a vertical connection structure on a side of the module structure, the vertical connection structure vertically extending and connected to the first redistribution substrate,
wherein the module structure comprises:
an interposer substrate comprising a glass substrate, and
a first semiconductor chip mounted on the interposer substrate; and
a second semiconductor chip mounted on the interposer substrate.

2. The semiconductor package of claim 1, wherein the vertical connection structure comprises a connection substrate on the first redistribution substrate, the connection substrate having an opening that penetrates the connection substrate,
wherein the module structure is in the opening, and
wherein the first molding layer fills an area between the connection substrate and the module structure in the opening.

3. The semiconductor package of claim 2, wherein the connection substrate comprises a base layer and a conductive member in the base layer, and
wherein the base layer of the connection substrate comprises a polymer.

4. The semiconductor package of claim 1, wherein the first molding layer covers the first semiconductor chip and the second semiconductor chip.

5. The semiconductor package of claim 1, wherein the interposer substrate directly contacts a top surface of the first redistribution substrate, and
wherein a wiring pattern of the interposer substrate is connected to a wiring pattern of the first redistribution substrate.

6. The semiconductor package of claim 1, wherein the first redistribution substrate comprises a dielectric pattern, and
wherein the dielectric pattern comprises a polymer.

7. (canceled)

8. The semiconductor package of claim 7, wherein the first semiconductor chip comprises a plurality of chip vias that vertically penetrate the first semiconductor chip, and
wherein the plurality of chip vias of the first semiconductor chip are connected to a wiring pattern of the second redistribution substrate.

9. The semiconductor package of claim 7, further comprising an upper package on the second redistribution substrate.

10. The semiconductor package of claim 1, wherein each of the first semiconductor chip and the second semiconductor chip is coupled to the interposer substrate through a solder ball or a bonding wire, or
a first chip pad of the first semiconductor chip and a second chip pad of the second semiconductor chip are directly connected to a wiring pattern of the interposer substrate.

11. The semiconductor package of claim 1, wherein the module structure further comprises a second molding layer on the interposer substrate, the second molding layer covering the first semiconductor chip and the second semiconductor chip, and
wherein a width of the second molding layer is the same as a width of the interposer substrate.

12. The semiconductor package of claim 1, wherein the interposer substrate comprises:
a core portion comprising a glass fiber;
an upper buildup portion on a top surface of the core portion; and
a lower buildup portion on a bottom surface of the core portion, and
wherein the first semiconductor chip and the second semiconductor chip are mounted on the upper buildup portion.

13. The semiconductor package of claim 12, wherein the first semiconductor chip and the second semiconductor chip are electrically connected through the upper buildup portion.

14. A semiconductor package comprising:
a first redistribution substrate;
a connection substrate on the first redistribution substrate, the connection substrate having an opening that penetrates the connection substrate;
a module structure on the first redistribution substrate and in the opening of the connection substrate; and
a first molding layer on the first redistribution substrate, the first molding layer covering the module structure and the connection substrate,
wherein the module structure comprises:
an interposer substrate;
a first semiconductor chip on the interposer substrate; and
a second semiconductor chip on the interposer substrate,
wherein the interposer substrate comprises:
a core portion;
an upper buildup portion on a top surface of the core portion; and
a lower buildup portion on a bottom surface of the core portion,
wherein the first semiconductor chip and the second semiconductor chip are electrically connected through the upper buildup portion, and
wherein the lower buildup portion directly contacts the first redistribution substrate.

15. The semiconductor package of claim 14, wherein the core portion comprises glass or silicon (Si).

16. The semiconductor package of claim 14, further comprising a second redistribution substrate on the first molding layer,
wherein the connection substrate connects the first redistribution substrate to the second redistribution substrate.

17. The semiconductor package of claim 16, wherein the first semiconductor chip comprises a plurality of chip vias that vertically penetrate the first semiconductor chip, and
wherein the plurality of chip vias of the first semiconductor chip are connected to a wiring pattern of the second redistribution substrate.

18. The semiconductor package of claim 16, further comprising an upper package on the second redistribution substrate.

19. (canceled)

20. The semiconductor package of claim 14, wherein the first molding layer covers the first semiconductor chip and the second semiconductor chip.

21. (canceled)

22. (canceled)

23. (canceled)

24. The semiconductor package of claim 14, wherein the module structure further comprises a second molding layer on the interposer substrate, the second molding layer covering the first semiconductor chip and the second semiconductor chip, and
wherein a width of the second molding layer is the same as a width of the interposer substrate.

25. A semiconductor package comprising:
a first redistribution substrate;
a second redistribution substrate on the first redistribution substrate;
a connection substrate that connects the first redistribution substrate to the second redistribution substrate, the connection substrate having an opening that penetrates the connection substrate;
a module structure between the first redistribution substrate and the second redistribution substrate, the module structure being in the opening of the connection substrate;
a plurality of external terminals on a bottom surface of the first redistribution substrate; and
an upper package mounted on the second redistribution substrate,
wherein the module structure comprises:
an interposer substrate connected to the first redistribution substrate; and
a first semiconductor chip on the interposer substrate; and
a second semiconductor chip on the interposer substrate and spaced apart from the first semiconductor chip, and
wherein a core portion of the interposer substrate and a dielectric pattern of the first redistribution substrate comprise different materials from each other.

26. (canceled)

27. (canceled)

28. (canceled)

29. (canceled)

30. (canceled)

31. (canceled)

32. (canceled)

33. (canceled)

34. (canceled)
